(19) United States
(12) Patent Application Publication
(10) Pub. No.: US 2011/0192634 A1
(43) Pub. Date: Aug. 11, 2011

(54) Circuit Board

(76) Inventor: Ping Wang, Shenzhen (CN)

(21) Appl. No.: 13/120,421

(22) PCT Filed: Sep. 23, 2009
(86) PCT No.: PCT/CN2009/074164

§ 371 Date: Mar. 22, 2011

(30) Foreign Application Priority Data
Sep. 24, 2008 (CN) 200820212164.0

(51) Int. Cl. H05K 1/00

(52) U.S. Cl. 174/250

(57) ABSTRACT

A circuit board comprises at least one mounting hole for coupling a weld screw. At least one notch for receiving solder is formed in an inner wall of the mounting hole.

### CROSS-REFERENCE TO RELATED APPLICATIONS

This application claims priority to, and benefit of Chinese Patent Application No. 200820212164.0 filed to the State Intellectual Property Office of P.R. China on Sep. 24, 2008, the invention of which is incorporated by reference herein in its entirety.

### FIELD OF THE INVENTION

The present invention relates to an integrated circuit device, more particularly, to an improvement of a circuit board.

### BACKGROUND OF THE INVENTION

Usually, finished circuit boards of electric devices are fixed to a shell using binding screws, and the circuit boards have mounting holes for connecting screws. For high power density modules, there have to be enough safe space around the mounting holes, where there cannot be any electronic components to avoid short circuit. This arrangement wastes space and increases design cost.

An effective way to solve the problem is to use a T-shaped weld screw to save circuit space. As shown in FIG. 2, the weld screw 2 includes a welded part 20, a connected part 21, and a threaded hole 22. As shown in FIGS. 1 and 3, circuit board 1 has mounting hole 10, where the welded part 20 is welded. The threaded hole 22 is screwed on the screw 30. Then the circuit board 1 is fixed to the shell 3. However, such a welded connection makes it difficult to fill solder, and the weld screws may fall off easily during a vibration test.

### SUMMARY OF THE INVENTION

The present invention is directed to solve at least one of the problems existing in the prior art. Thus, the present invention provides a circuit board with a mounting hole having a notch, by which the difficulty in filling solder may be overcome with enhanced soldering quality.

According to an aspect of the invention, a circuit board may comprise at least one mounting hole to couple a weld screw. The mounting hole comprises at least one notch for receiving solder which is formed in an inner wall of the mounting hole.

According to another aspect of the invention, the notch may run through an upper surface of the circuit board to a lower surface of the circuit board.

In another embodiment, the notch may be recessed from the upper surface of the circuit board by a certain height to form a step.

According to yet another aspect of the invention, the mounting hole may comprise two or more notches, which provide a uniform distribution around the circumference of the mounting hole.

In one embodiment, an affinity layer for the solder is coated on the inner wall of the mounting hole.

In some embodiments, the weld screw comprises a welded part, a connected part connected with the welded part, and a threaded hole formed into the connected part. And a maximal dimension of the notch in a radial direction is greater than a radius of the connected part of the weld screw.

According to the present invention, when circuit boards are fixed to some components, such as a shell, it does not affect configurations of components on the circuit board and reduces the safe distance with no need to reserve space for screws. Therefore, it provides enough space for electronic components in the high power density modules. Screws do not penetrate through and protrude out of the nuts and there is no need to additionally reserve space for screws. As a result, the nuts may be configured as desired, such as lying below elevating devices, to save layout space. Meanwhile, by forming notches for receiving solder around a mounting hole, solder can seep through the notches, which makes welding more reliable and observation easier. Furthermore, the present invention can be achieved easily.

More aspects and advantages of the present invention will be described below, at least a part of which will be clear in the following description accompanying the figures as attached, and/or be obvious for a person normally skilled in the art from embodiments described hereinafter.

### BRIEF DESCRIPTION OF THE DRAWINGS

The aforementioned features and advantages of the invention as well as additional features and advantages thereof will be more clearly understood hereinafter as a result of a detailed description of preferred embodiments when taken in conjunction with the drawings, wherein:

FIG. 1 is an exploded perspective view of components in a prior art circuit board;

FIG. 2 is a sectional view of a prior art weld screw;

FIG. 3 is a sectional view of a weld screw and a circuit board assembled in prior art;

FIG. 4 is a sectional view of a weld screw and a circuit board assembled according to a second embodiment of the invention;

FIG. 5 is a sectional view of a weld screw and a circuit board assembled according to a third embodiment of the invention;

FIG. 6 is a sectional view of a weld screw and a circuit board assembled according to a fourth embodiment of the invention;

FIG. 7 is a plan view of a circuit board with one via-hole notch according to one embodiment of the invention;

FIG. 8 is a plan view of a circuit board with two via-hole notches according to one embodiment of the invention;

FIG. 9 is a plan view of a circuit board with four via-hole notches according to one embodiment of the invention;

FIG. 10 is a plan view of the circuit board shown in FIG. 6;

FIG. 11 is a plan view of a circuit board with a cylindrical via-hole notch according to one embodiment of the invention;

FIG. 12 is a plan view of a circuit board with one notch formed as a step according to one embodiment of the invention;

FIG. 13 is a plan view of a circuit board with two notches formed as steps respectively according to one embodiment of the invention;

FIG. 14 is a plan view of a circuit board with four notches formed as steps respectively according to one embodiment of the invention;

FIG. 15 is a plan view of a circuit board with a cylindrical notch formed as a step according to one embodiment of the invention;

FIG. 16 is a sectional view of a structure according to a first embodiment of the invention;

FIG. 17 is a left view of the structure shown in FIG. 16; and

FIG. 18 is a plan view of the structure shown in FIG. 16.

### DETAILED DESCRIPTION OF THE PREFERRED EMBODIMENT

Reference will now be made in detail to embodiments of the present invention. The embodiments described herein with reference to drawings are explanatory, illustrative, and used to generally understand the present invention. The embodiments shall not be construed to limit the scope of the present invention. The same or similar elements and the elements having same or similar functions are denoted by like reference numerals throughout the descriptions.

Further, in the entire and through description, relative terms such as “longitudinal”, “lateral”, “front”, “rear”, “right”, “left”, “lower”, “upper”, “horizontal”, “vertical”, “above”, “below”, “up”, “top”, “bottom” as well as derivative thereof shall be construed to refer to the orientation as then described or as shown in the drawings under discussion. These relative terms are for convenience of description and do not require that the present invention be constructed or operated in a particular orientation. Terms concerning attachments, coupling and the like, such as “connected” and “interconnected”, refer to a relationship wherein structures are secured or attached to one another either directly or indirectly through intervening structures, as well as both movable or rigid attachments or relationships, unless expressly described otherwise.

### First Embodiment

A circuit board 1 comprises at least one mounting hole 10 for coupling a weld screw 2, and at least one notch 100 for receiving solder is formed in an inner wall of the mounting hole, as shown in FIG. 4, for example. In this embodiment, a thickness of the circuit board 1 is about 2 mm As shown in FIG. 2, the weld screw 2 is a T-shaped screw, which comprises a welded part 20, a connected part 21, and a threaded hole 22. The welded part 20 is welded in the mounting hole 10, and the threaded hole 22 is screwed to the screw 30. In this embodiment, the welded part 20 has a diameter of about 4 mm and a height of about 2 mm. The connected part 21 has a diameter of about 6 mm and a height of about 3.3 mm. It should be noted that the T-shaped screw and the configuration or shape of the mounting hole are only for illustrative purpose rather than limitation.

The threaded hole 22 is a blind hole or a counter sink, so that solder can be applied over the welded part 20 for welding. In this embodiment, the threaded hole 22 extends to the welding part 20 without protruding out thereof. Then there could be enough thread length for screws to be connected reliably.

The mounting hole 10 on the circuit board 1 is used to be welded with the welded part 20 of the weld screws 2. The size of the mounting hole 10 can be slightly larger than or substantially the same as that of the welded part 20. Then the welded part 20 can be easily inserted into the mounting hole 10. For convenience, a side of the circuit board on which electronic components are placed is referred to as the first surface, the other side is referred to as the second surface.

The shape of the mounting hole 10 may be circular, rectangular or any other shape, which depends on the shape of the welded part 20 of the weld screws 2. Of course, it is preferable to choose a standard weld screw with the shape and size of the mounting hole to be matched.

In this embodiment, the shape of the mounting hole 10 and welded part 20 are both circular. The diameter of the connected part 21 is greater than the diameter of the welded part 20 and also greater than the diameter of mounting hole 10. The diameter of the welded part 20 is slightly smaller than that of the mounting hole 10. And the height of the welded part 20 is substantially equal to the thickness of the circuit board 1 to prevent the weld screws 2 from protruding out of the first surface to save space. The welded part 20 is inserted into the mounting hole 10, and the connected part 21 rests on the circuit board 1 to position the weld screw 2 in in the vertical direction.

The notch 100 may be made using a conventional perforating method. In this embodiment, the circuit board 1 is processed by an NC machine tool: Firstly, the mounting hole 10 with a diameter of 4 mm is made. Then the notch 100 is made around the circumference of the mounting hole 10. In another embodiment, more easily, the notch 100 can be made by manual perforating.

The notch 100 is used for receiving solder. The size and shape of notch 100 are not limited to those described herein.

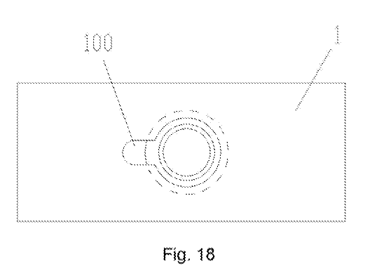

In this embodiment, as shown in FIGS. 16-18, the notch 100 is a via-hole notch extending from the first surface to the second surface, and the distance between the vertex of the notch 100 and the center of mounting hole 10 is greater than the radius of the connected part 21. In other words, a maximal dimension of the notch 100 in a radial direction is greater than the radius of the connected part of the weld screw.

The mounting hole 10 has an affinity layer in the inner surface or wall for enhancing the affinity with solder. The affinity layer can be, but not limited to, a Ni/Au alloy electroplate layer or Sn/Pd alloy electroplate layer.

### Second Embodiment

The present embodiment is similar to the first embodiment. Therefore, the same or similar detailed description thereof is hereby omitted for clarity purpose.

The present embodiment provides another type of notch. As shown in FIGS. 4 and 7, the cylindrical mounting hole 10 has a notch 100 formed on its wall, and the notch 100 is a via-hole notch extending from the upper surface of circuit board 1 to the lower surface of circuit board 1. The via-hole notch may be a rectangular one, which can be easily formed by punching.

### Third Embodiment

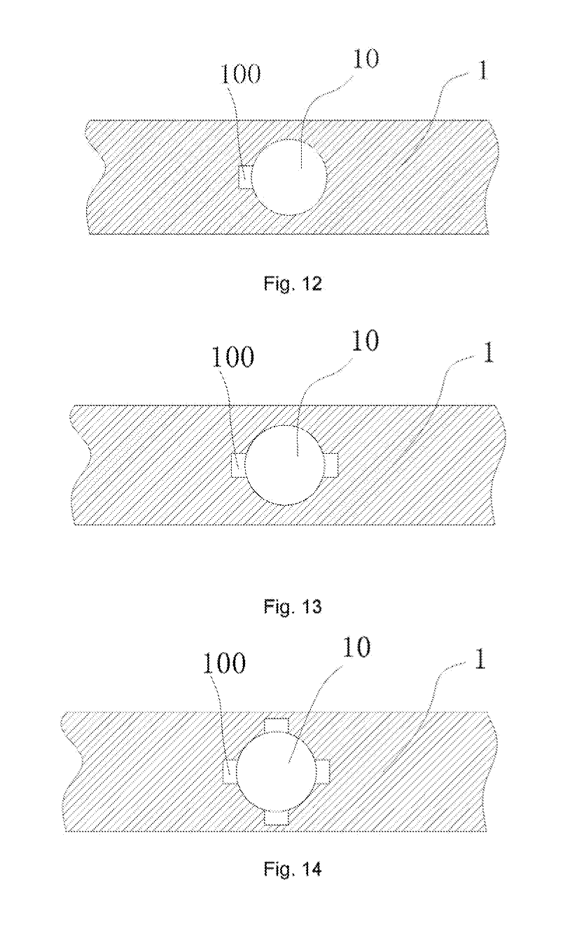

The present embodiment is similar to the first embodiment. Therefore, the same or similar detailed description thereof is hereby omitted for clarity purpose. In the present embodiment, another type of notch is provided. As shown in FIGS. 5 and 12, the notch 100 does not run through the whole circuit board, but is formed as steps or a counter sink from the upper surface of the circuit board 1 to the lower surface of the circuit board 1.

### Fourth Embodiment

The present embodiment is similar to the first embodiment. Therefore, the same or similar detailed description thereof is hereby omitted for clarity purpose.

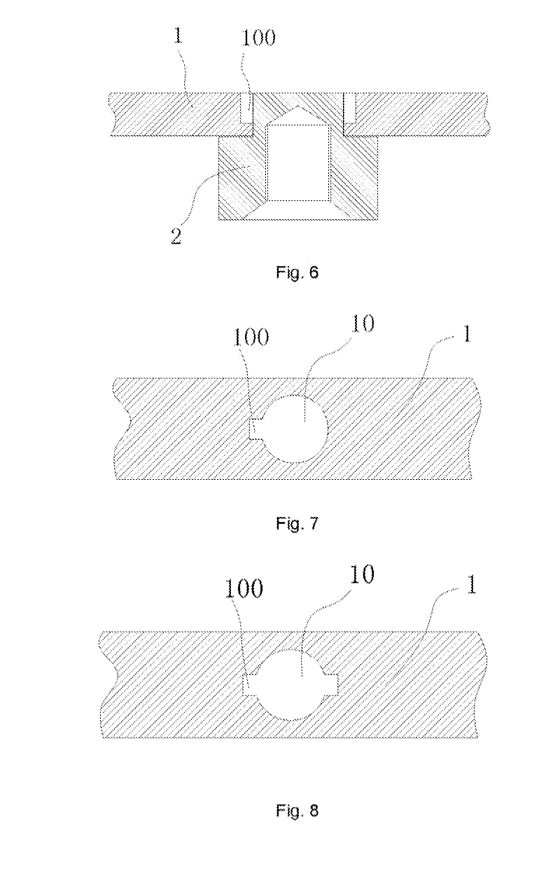

In the present embodiment, yet another type of notch is provided. As shown in FIG. 6 and FIG. 10, the only difference between the notch 100 in this embodiment and the notch 100 in the third embodiment lies in that the shape of the step is annular.

### Fifth Embodiment

The present embodiment is similar to the first embodiment. Therefore, the same or similar detailed description thereof is hereby omitted for clarity purpose.

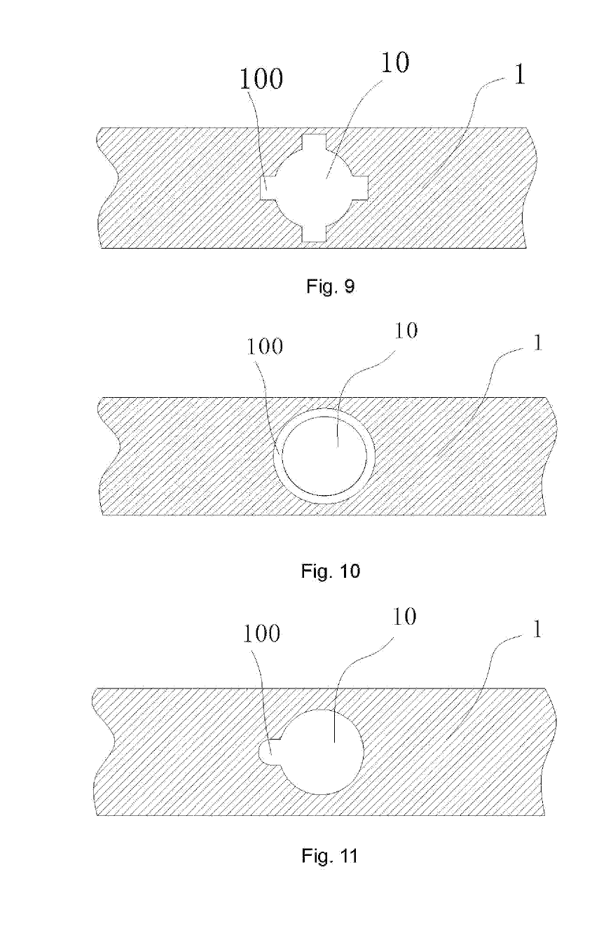

The mounting hole 10 could have two or more notches. For example, in FIG. 8, two via-hole notches 100 are placed symmetrically around the circumference of the mounting hole 10. In FIG. 9, four via-hole notches 100 are placed symmetrically around the circumference of the mounting hole 10. In FIG. 13, two notches 100 formed as steps are placed symmetrically around the circumference of the mounting hole 10. In FIG. 14, four step-form notches 100 are placed symmetrically around the circumference of the mounting hole 10.

### Sixth Embodiment

The present embodiment is similar to the first embodiment. Therefore, the same or similar detailed description thereof is hereby omitted for clarity purpose.

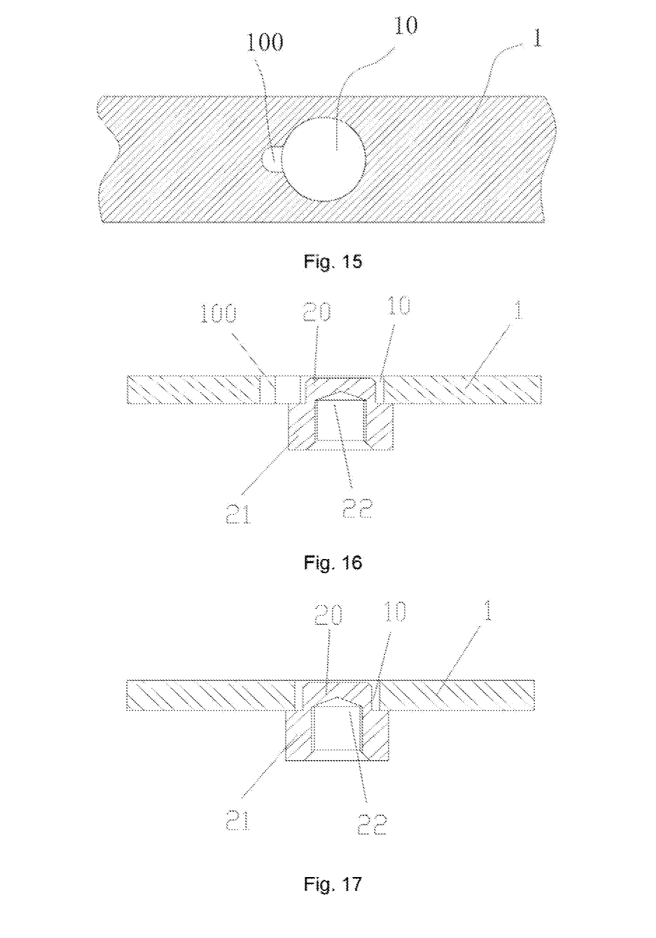

The via-hole notch can be a rectangular hole, and also can be a cylindrical notch. FIG. 11 shows a circuit board 1 with a cylindrical via-hole notch 100. FIG. 15 shows a circuit board 1 with a cylindrical notch 100 formed as steps.

The following is a detailed description of a assembly process with reference to the drawings.

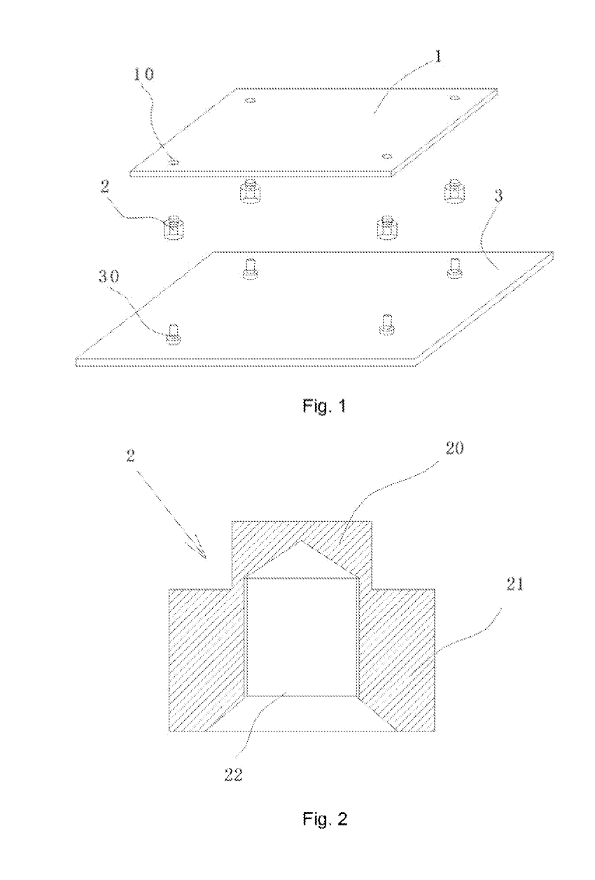

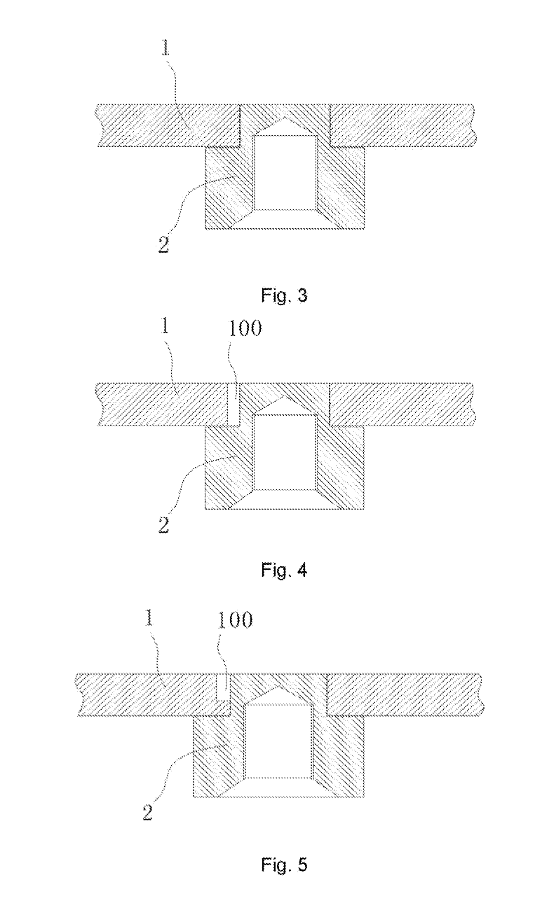

As shown in FIG. 1, the welded part 20 of the weld screw 2 is inserted to the mounting hole 10 of the circuit board 1. The connected part 21 is pressed against the circuit board 1 around the circumference of the mounting hole 10. Then, welding is performed. The gap between the wall of mounting hole 10 and the outside wall of welded part 20 is filled with solder. With the affinity effect of solder on the surface of the affinity layer of the welded part 20, the solder quickly diffuses between the connected part 21 and the outside surface of the thread hole 22, thus forms a strong welding ring. Moreover, a part of the solder seeps through the notch 100, which makes it easy to observe the welding state. The welding may be manual welding or wave soldering. Finally, the screw 30 is connected to the threaded hole 22 through the shell 3, and then the circuit board 1 is fixed to the shell 3.

Although the preferred embodiments of the present invention have been described above, the present invention is not limited to the above words, those who skilled in this field shall understand that many amendments, replacements or variations may be made according to the present invention, which are all within the protection of the present invention.

1. A circuit board, comprising at least one mounting hole for receiving a weld screw, wherein at least one notch for receiving solder is formed in an inner wall of the mounting hole.

2. The circuit board of claim 1, wherein the mounting hole is a circular via hole or a rectangular via hole.

3. The circuit board of claim 1, wherein the notch is a via-hole notch extending from an upper surface of the circuit board to a lower surface of the circuit board.

4. The circuit board of claim 1, wherein the notch is formed as steps which are recessed from the upper surface of the circuit board.

5. The circuit board of claim 1, wherein an affinity layer to the solder is coated on the inner wall of the mounting hole.

6. The circuit board of claim 1, wherein the weld screw comprises a welded part, a connected part connected with the welded part and a threaded hole formed into the connected part; and a maximal dimension of the notch in a radial direction is greater than a radius of the connected part of the weld screw.

7. The circuit board of claim 1, wherein the mounting hole comprises two or more notches.

8. The circuit board of claim 6, wherein the notches are uniformly distributed around a circumference of the mounting hole.

9. A circuit board comprising at least one mounting hole for receiving a weld screw, and the mounting hole is a circular via hole or a rectangular via hole, wherein at least one notch for receiving solder is formed in an inner wall of the mounting hole, and an affinity layer to the solder is coated on the inner wall of the mounting hole.

10. The circuit board of claim 9, wherein the notch is a via-hole notch extending from an upper surface of the circuit board to a lower surface of the circuit board.

11. The circuit board of claim 9, wherein the notch is formed as steps which are recessed from the upper surface of the circuit board.

12. The circuit board of claim 9, wherein the weld screw comprises a welded part, a connected part connected with the welded part and a threaded hole in the connected part; and a maximal dimension of the notch in a radial direction is greater than a radius of the connected part of the weld screw.

13. The circuit board of claim 9, wherein the mounting hole comprises two or more notches.

14. The circuit board of claim 13, wherein the notches are uniformly distributed around a circumference of the mounting hole.
